(19) United States
(12) Patent Application Publication
(10) Pub. No.: US 2004/0090834 A1
(43) Pub. Date: May 13, 2004

(54) Based pad layout for reducing parasitic base-collector capacitance and method of fabricating HBT using the same

(76) Inventors: Kyoung Hoon Yang, Daejon (KR); Yong Joo Song, Daejon (KR)

Correspondence Address: HARNESS, DICKEY & PIERCE, P.L.C., P.O. BOX 828, BLOOMFIELD HILLS, MI, 48303, US

(21) Appl. No.: 10/666,755

(22) Filed: Sep. 17, 2003

(30) Foreign Application Priority Data
Nov. 12, 2002 (JP) 2002-700044

(51) Int. Cl. G11C 7/00

(52) U.S. Cl. 365/200

(57) ABSTRACT

The present invention relates to a base pad layout for reducing the parasitic base-collector capacitance and method of fabricating HBT using the same.

The present invention comprises a base region which is aligned in a <011> or <011> orientation with respect to the semiconductor substrate; a base pad region which has a fixed slope with respect to said base region; and a base feeding region which is aligned in a <010> orientation and connects said base region and said base pad region.

According to the present invention, the base-collector capacitance due to base pad could be reduced through a simple base pad layout and wet etching which isolates an active base region and a base pad region.

The present invention uses the conventional wet etching method for fabricating a triple mesa HBT involving only a modification of the base pad layout, hence, no additional process is required.

### BACKGROUND OF THE INVENTION

The present invention relates to a base pad layout for reducing the parasitic base-collector capacitance and method of fabricating HBT using the same. More particularly, the invention relates to a Heterojunction Bipolar Transistor fabricating (HBT) method where the base-collector capacitance due to base pad could be reduced through a simple base pad layout that utilizes the fabricating method of a triple mesa heterojunction bipolar transistor using wet etching which isolates an active base region and a base pad region.

Currently, a worldwide active research work is being undertaken in the area of ultra-high speed wide-band cable and wireless communication in order to meet an explosive increase in Internet users and a rapid shift towards a high capacity data transmission for moving image files from a low capacity data transmission for simple pictures or text files.

Some of the ultra-high speed wide-band communication networks include Local Multipoint Distribution Services (LMDS) (28 GHz band) for wireless communication and optical fiber communication (OC-768 (40 Gbps optical fiber network))

In order to meet the rapid increase in information services, more bandwidth should be available in the future. At the present, active research on the ultra-high speed wide-band communication networks for a bandwidth over 100 Ghz is being carried out.

Most of all, the miniaturization, performance improvement and development of semiconductor devices that function in the high frequency band are very important in order to construct ultra-high speed wide-band communication networks.

Accordingly, high-speed performance semiconductor devices are actively being researched.

Especially, a heterojunction bipolar transistor is attracting a lot of attention as an ultra high frequency semiconductor device that can be used to transmit/receive data in an ultra high-speed communication network. Active research is being concentrated on reducing the parasitic component of the device for a better ultra high-speed performance.

It has been discovered that the ultra high-speed performance of HBT is constraint by the base-collector capacitance. To date, many research works on reducing the base-collector capacitance for an ultra high-speed performance have been published.

The maximum oscillation frequency fmax can be approximated by base resistance RB, base collector capacitance CBC and current gain cutoff frequency fT as shown in Equation 1

$${f}_{max} = \sqrt{\frac{{f}_{T}}{8 π {R}_{B} {C}_{BC}}} \qquad [ Equation 1 ]$$

As can be seen from Equation 1, the performance speed of HBT increases with a decrease in the base-collector capacitance.

The above base-collector capacitance can largely be separated into the capacitance due to an active base region and the capacitance due to a base pad for inteconnect via.

With the improvement in the device fabrication technology recently, the active base region is being scaled down proportionately with the scale down of the active region. However, the scale down of the base pad is harder to achieve due to the complexity of the via process.

Accordingly, the recent technology allows an almost equal size for both base region and base pad region.

More specifically, in accordance with the scale down of the devices, the size of the parasitic capacitances for both base region and base pad region are almost equal. For the perspective of reducing the base-collector capacitance, it is of paramount importance to reduce the capacitance in the base pad region.

U.S. Pat. Nos. 4,380,774 (Title: High performance bipolar microwave transistor) and U.S. Pat. No. 5,672,522 (Title: Method of making selective sub-collector heterojunction bipolar transistor) both disclose methods for reducing the base-collector capacitance using the base pad of HBT.

These prior arts rely on ion implantation and epitaxy re-growth methods for reducing the base-collector capacitance. However, these methods require costly equipment such as ion implantation apparatus and also involves an epitaxy re-growth process that is associated with the reliability and repeatability problems.

Hyunchol Shin, Gaessler C., and Leier H. disclose other prior arts on double polyimide planarization process, titled as “Reduction of base-collector capacitance in lnP/lnGaAs HBT's using a novel double polyimide planarization process”, in IEEE Electron Device Letters (Volume 14, Issue 8, pp 297-299, August 1998). However, the fabrication process disclosed in the paper is very complicated and the process involves a reactive ion etching that could damage the HBT device.

### SUMMARY OF THE INVENTION

The present invention is designed to overcome the above problems of prior art. The object of the present invention is to provide a Heterojunction Bipolar Transistor fabricating (HBT) method where the base-collector capacitance due to base pad could be reduced through a simple base pad layout that utilizes the fabricating method of a triple mesa heterojunction bipolar transistor using wet etching which isolates an active base region and a base pad region.

According to the present invention, the base pad layout for reducing the parasitic base-collector capacitance comprises a base region aligned in a <011> or <011> orientation with respect to the semiconductor substrate and a base feeding region which connects the base region and the base pad region.

The method for fabricating a triple mesa HBT using the base pad layout according to the present invention comprises the processing steps of: a first process for isolating a base region and a base pad region and forming a base pad layout by connecting said regions to a base feeding region; a second process for sequentially stacking a sub-collector InGaAs layer/an etching stopper lnP layer/a base-collector lnGaAs layer/an emitter lnP layer/an emitter cap lnGaAs layer on a semi-insulating lnP substrate using the epitaxy growth method; a third process for depositing a base metal using said base pad layout as a mask after depositing a emitter metal on the epitaxy structure formed in said second process and sequentially etching the emitter cap lnGaAs layer and the emitter lnP layer to allow said emitter metal to self-align and to expose the upper side of the base-collector lnGaAs layer; a fourth process for defining a first photoresist to some parts of the base region and the base feeding region in order to protect an emitter region; a fifth process for forming a void area underneath the base feeding region using side etching after exposing the upper side of the sub-collector lnGaAs layer by etching the base-collector lnGaAs layer and the etching stopper lnP layer using said first photoresist and base metal layer as a mask; a sixth process for depositing a collector metal on said sub-collector lnGaAs layer; and a seventh process for defining a second photoresist in order to protect the lower part of the emitter and the base region and removing said second photoresist after isolating the base region and the base pad region by side etching the sub-collector lnGaAs layer.

### BRIEF DESCRIPTION OF THE DRAWINGS

FIG. 1 shows a plan view of the base pad layout according to the present invention where FIG. 1a shows a <01 1> orientation and FIG. 1b shows a <011>orientation.

FIG. 2 shows a standard epitaxy structure for the HBT device that is required by the present invention.

FIGS. 3a through 3f show cross section diagrams of the HBT device according to the fabrication process of the present invention.

FIG. 4 shows a structural diagram of the HBT device fabricated according to the fabrication process of the present invention.

FIG. 5 shows an electro-microscopic picture of the HBT device fabricated according to the fabrication process of the present invention.

### DESCRIPTION OF THE NUMERIC ON THE MAIN PARTS OF THE DRAWINGS

111: Semi-Insulating lnP Substrate

112: Emitter Cap InGaAs Layer

113: Emitter InP Layer

114: Base-Collector InGaAs Layer

115: Etching Stopper InP Layer

116: Sub-Collector InGaAs Layer

121: Emitter Metal Layer

122: Base Metal Layer

122a: Base Pad Region

122b: Base Feeding Region

122c: Base Region

123: Collector Metal Layer

131, 132: Photoresist

### DETAILED DESCRIPTION OF THE EMBODIMENTS

Hereinafter, preferred embodiments of the present invention will be described in detail with reference to the accompanying drawings.

The methods disclosed in the present invention could both be implemented to a single HBT and double HBT. The preferred embodiments hereafter will be described with reference to the single HBT.

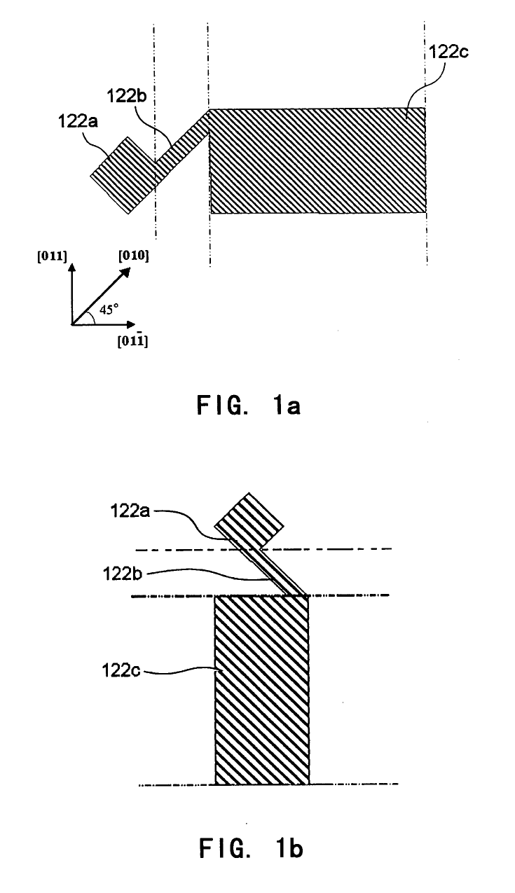

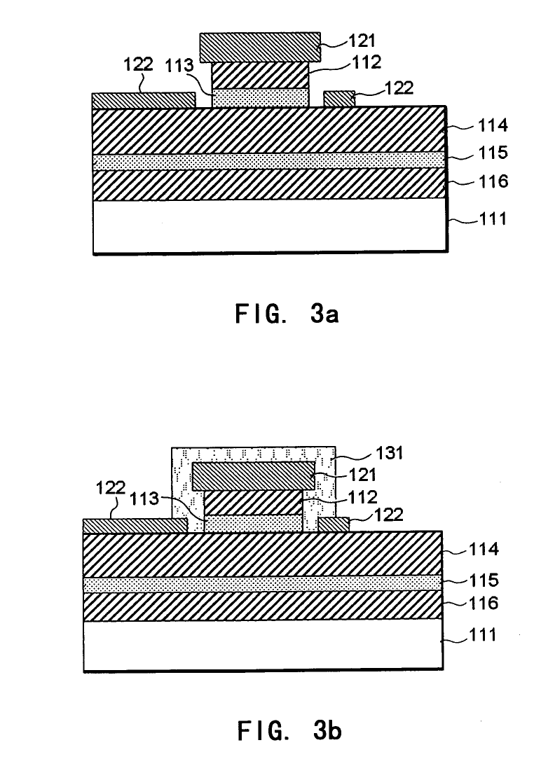

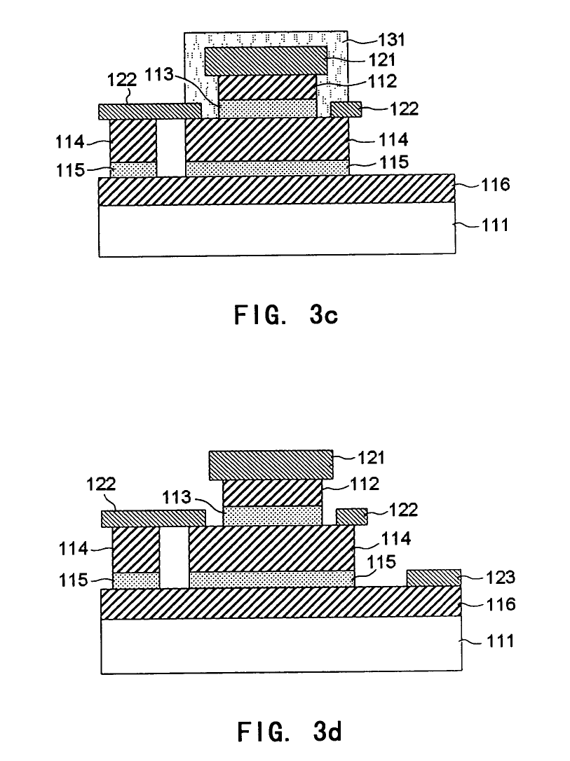

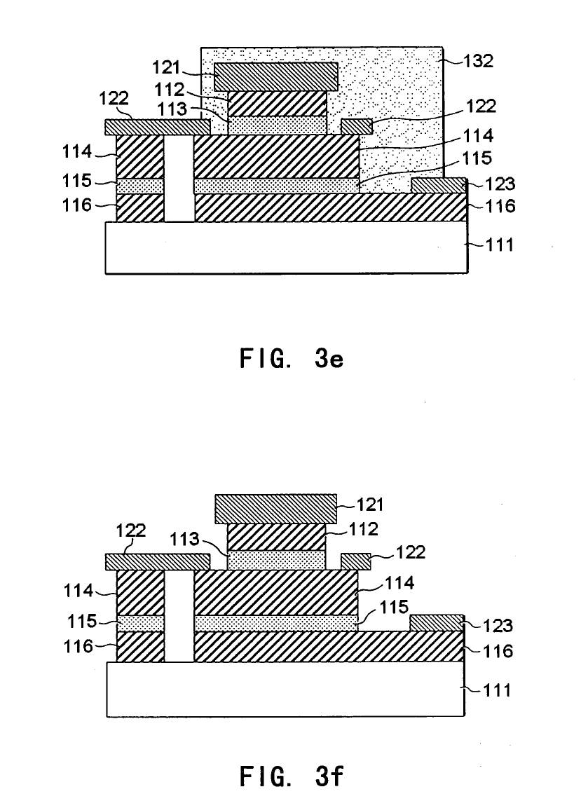

FIG. 1 shows a base pad layout as a mask layout for depositing the base metal layer 122 in FIG. 3a.

The base pad layout comprises a base region 122c aligned in a <01 1> or <011> orientation on the substrate; a base pad region 122a aligned in a rectangular shape (square or rectangular) which is sloped (45 degree) against said base region 122c and a base feeding region 122b aligned in a <010>orientation and connects said base region 122c and said base pad region 122a.

The main feature of the present invention is isolating the base region 122c and the base pad region 122a and forming a base pad layout by connecting the regions to the base feeding region 122b. This differentiates the present invention with other methods that define a base pad region on an extended part of the conventional base region.

Above all, this structure as shown in FIG. 3 is for forming a void area between the base pad region 122a and the base region 122c by side etching underneath the base feeding region 122b.

This base pad layout is based on the facts that the etching speed is faster in <010> direction than <011> or <011> direction and almost no etching occurs in <011> direction when wet etching the lnP layer.

Utilizing the above layout, all epitaxy structures except the semi-insulating lnP substrate 111 can be etched to reduce the base-collector capacitance for the lower part of the base feeding region 122b as shown in FIG. 3e.

By isolating the base region 122c and the base pad region 122a, the parasitic capacitance could be electrically isolated from the HBT's base-collector capacitance.

The lnP layer and lnGaAs layer underneath the base pad region 122a simply act as a post which supports the base pad region 122a without having any electrical role. As a result, the base-collector capacitance due to the base pad is significantly reduced.

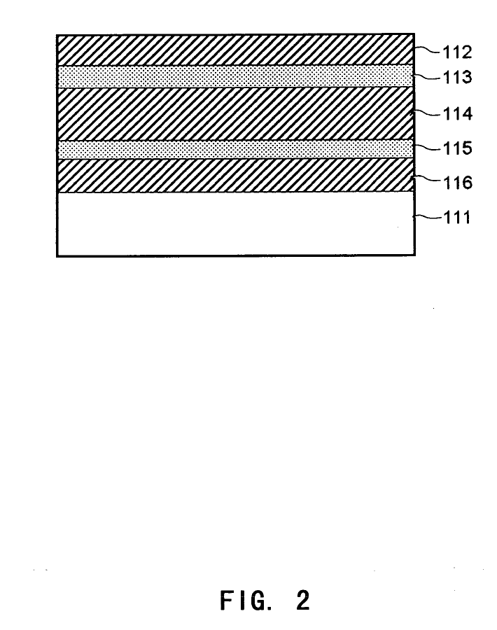

FIG. 2 shows a standard epitaxy structure for lnP/lnGaAs SHBT or DHBT that is required by the present invention.

Using the epitaxy growth methods such as MetalOrganic Chemical Vapour Deposition MOCVD or Molecular Beam Epitaxy (MBE), an sub-collector InGaAs layer 116/an etching stopper lnP layer 115/a base-collector lnGaAs layer 114/an emitter lnP layer 113/an emitter cap lnGaAs layer 112 are sequentially stacked on a semi-insulating lnP substrate 111.

FIGS. 3a through 3f show cross section diagrams of the HBT devices which are fabricated according to the present invention.

The fabrication method of the HBT devices according to the present invention which comprises the step of depositing an emitter metal layer 121 which aligned in a <011> or <011> orientation in FIG. 3 on the epitaxy structure as shown in FIG. 2; sequentially etching the emitter cap lnGaAs layer 112 and the emitter lnP layer 113 to allow the base metal layer to self-align; and depositing the base metal layer 122 on the upper part of the base-collector lnGaAs layer 114 using the base pad layout 112a, 122b, 122c as a mask.

Afterwards, a photoresist pattern 131 for protecting the emitter region as shown in FIG. 3b is defined on some parts of base feeding region 133 and based region 122c.

Afterwards, the base-collector lnGaAs layer 114 and the etching stopper lnP layer 115 are sequentially etched using the photoresist pattern 113 and base metal layer 122 as an etching mask.

In this process, the base pad region and base region are isolated by side etching underneath the base feeding region using the anisotropic etching characteristic where the etching speed varies according to the crystal lattice direction.

In this case, the etchant used is H3PO4:H2O2:H2O as in the case of etching base-collector InGaAs layer 114.

Due to a high selectivity value between the etching stopper lnP layer 115 and the base-collector lnGaAs layer 114 for the etchant H3PO4:H2O2:H2O, almost no etching occurs for the etching stopper lnP layer 115.

Also, due to a high selectivity value between the etching stopper lnP layer 115 and the sub-collector InGaAs layer 116 for the etchant HCl: H3PO4, almost no etching occurs for the sub-collector InGaAs layer 116.

In another words, the sub-collector InGaAs layer 116 and the etching stopper lnP layer 115 could selectively be etched using the above etchant and small amount of over etching does not cause a serious problem.

In the above process, since the lower part of base feeding region (the void area underneath the left base metal layer 122 in FIG. 3c) is aligned in <010>direction, a fast side etching occurs resulting a void area.

In this instance, the etching speed is dependent upon the type of etchant, concentration and temperature.

Afterwards, a collector metal layer is deposited on the sub-collector InGaAs layer 116 as shown in FIG. 3d.

Afterwards, a photoresist pattern 132 is defined on the whole area except the base pad region 122a for protection and the sub-collector InGaAs layer 116 is etched as shown in FIG. 3e.

In this process, the base pad region and base region are isolated by side etching underneath the base feeding region using the anisotropic etching characteristic where the etching speed varies according to the crystal lattice direction.

In this case, the etchant used is H3PO4:H2O2:H2O as in the case of etching base-collector InGaAs layer 114.

Due to a high selectivity value between the etching stopper lnP layer 115 and the semi-insulating lnP substrate 111 for the etchant H3PO4:H2O2:H2O, almost no etching occurs for the etching stopper lnP layer 115.

In this instance, the etching speed is dependent upon the type of etchant, concentration and temperature.

In the above process, the base-collector capacitance could be reduced by etching the whole of the lower part of the base feeding region 122b (where a void area is formed) except the semi-insulating lnP substrate 111.

Also, by isolating the base region and the base pad region, the parasitic capacitance could be electrically isolated.

The lnP layer and lnGaAs layer underneath the base pad region simply act as a post which supports the base pad region without having any electrical role. As a result, the base-collector capacitance due to the base pad is significantly reduced.

Finally, the final HBT structure is completed by removing the photoresist pattern 132 as shown in FIG. 3f.

The base-collector InGaAs layer 114 which is used for a base collector layer for the single HBT could be a base layer for the double HBT. The lnP layer 115 which is used for an etching stopper layer for the single HBT could be a collector layer for the double HBT.

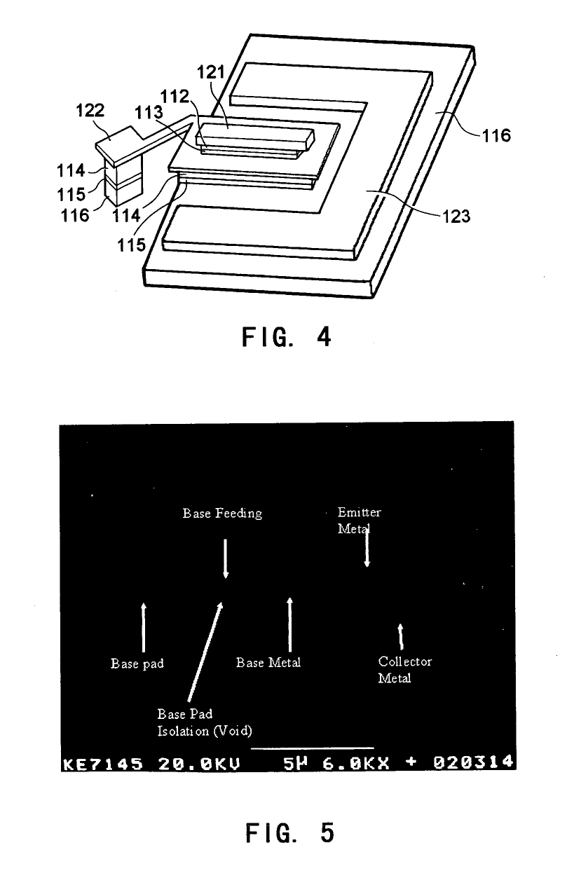

FIG. 4 shows the final HBT structure after undergoing the processes in FIG. 2 and FIGS. 3a through 3f.

FIG. 5 shows an electro-microscopic structure after undergoing the processes in FIG. 2 and FIGS. 3a through 3d.

FIG. 4 and FIG. 5 show the final results of the present invention.

As disclosed so far in the present invention, the base-collector capacitance due to base pad could be reduced through a simple base pad layout and wet etching which isolates an active base region and a base pad region.

Since the present invention uses the conventional wet etching method for fabricating a triple mesa HBT involving only a small modification of the base pad layout, no additional process is required.

The present invention provides a simple base pad layout that utilizes wet etching which isolates an active base region and a base pad region in order to reduce the base-collector capacitance from the base pad.

According to the present invention, the new base pad layout in the HBT device fabrication process uses the conventional process without the need for additional processes and brings about an economic advantage of reducing the time required for technological development.

Also, the new base pad layout could be applied not only to InP/InGaAs but also various types of compound semiconductors that use the mesa structure including Heterojunction Field Effect Transistor (HFET), Photo Diode, Photo Transistor.

What is claimed is:

1. A base pad layout for reducing the parasitic base-collector capacitance, comprising:
a base region which is aligned in a <011> or <011>orientation with respect to the semiconductor substrate;
a base pad region which has a fixed slope with respect to said base region; and
a base feeding region which is aligned in a <010>orientation and connects said base region and said base pad region.

2. The base pad layout as claimed in claim 1, wherein said base pad region is in a square or rectangular shape.

3. A method for fabricating a triple mesa HBT using the base pad layout, comprising the processing steps of:
a first process for isolating a base region and a base pad region and forming a base pad layout by connecting said regions to a base feeding region;
a second process for sequentially stacking a sub-collector InGaAs layer/an etching stopper lnP layer/a base-collector lnGaAs layer/an emitter lnP layer/an emitter cap lnGaAs layer on a semi-insulating lnP substrate using the epitaxy growth method;
a third process for depositing a base metal using said base pad layout as a mask after depositing a emitter metal on the epitaxy structure formed in said second process and sequentially etching the emitter cap lnGaAs layer and the emitter lnP layer to allow said emitter metal to self-align and to expose the upper side of the base-collector lnGaAs layer;
a fourth process for defining a first photoresist to some parts of the base region and the base feeding region in order to protect an emitter region;
a fifth process for forming a void area underneath the base feeding region using side etching after exposing the upper side of the sub-collector lnGaAs layer by etching the base-collector lnGaAs layer and the etching stopper lnP layer using said first photoresist and base metal layer as a mask;
a sixth process for depositing a collector metal on said sub-collector lnGaAs layer; and
a seventh process for defining a second photoresist in order to protect the lower part of the emitter and the base region and removing said second photoresist after isolating the base region and the base pad region by side etching the sub-collector lnGaAs layer.

4. The method as claimed in claim 3, wherein said etching in the fifth and seventh process involves a side etching of the lower part of the base feeding region using the anisotropic etching characteristic where the etching speed varies according to the crystal lattice direction.

5. The method as claimed in claim 3, wherein said etching in the fifth and seventh process involves a side etching of the lower part of the base feeding region using an etchant H3PO4:H2O2:H2O for the InGaAs layer and an etchant HCl:H3PO4 for the InP layer.

6. The method as claimed in claim 3, wherein the etching speed in the fifth and seventh process is dependent upon the type of etchant, concentration and temperature used.

7. The method as claimed in claim 3, wherein said lower part of the base feeding region undergoes a etching of the whole epitaxy structures except the semi-insulating lnP substrate in order to reduce the base-collector capacitance.

8. The method as claimed in claim 3, wherein if said HBT is a double HBT, then InGaAs layer becomes a base layer and the lnP layer becomes a collector layer.

9. The method as claimed in claim 4, wherein the etching speed in the fifth and seventh process is dependent upon the type of etchant, concentration and temperature used.

10. The method as claimed in claim 5, wherein the etching speed in the fifth and seventh process is dependent upon the type of etchant, concentration and temperature used.
